(19) United States
(12) Patent Application Publication
(10) Pub. No.: US 2008/0068917 A1
(43) Pub. Date: Mar. 20, 2008

(54) Controller for controlling a memory component in a semiconductor memory module

(76) Inventor: Srdjan Djordevic, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/589,983

(22) Filed: Oct. 31, 2006

(30) Foreign Application Priority Data
Sep. 18, 2006 (DE) 102006043669.5

(51) Int. Cl. G11C 8/00

(52) U.S. Cl. 365/230.01

(57) ABSTRACT

A control component for controlling at least one semiconductor memory component in a semiconductor memory module includes an address generator circuit for generating address signals. The address generator circuit generates different address signals based on the input of a configuration signal. The control component is operable to actuate semiconductor memory components from different generations, e.g., from the generations DDR2 and DDR3.

### CROSS REFERENCE TO RELATED APPLICATIONS

This application claims priority under 35 U.S.C. §119 to Application No. DE 102006043669.5 filed on Sep. 18, 2006, entitled “Control Component for Controlling at Least One Semiconductor Memory Component in a Semiconductor Memory Module,” the entire contents of which are hereby incorporated by reference.

### BACKGROUND

In a semiconductor memory module, a plurality of semiconductor memory components which communicate with their environment via a control component are disposed on a module board. FIG. 1 shows a module board MP holding semiconductor memory components 20. To control read or write access operations to the semiconductor memory components, a control component 10 is provided. The control component 10 is connected to the individual semiconductor memory components via various buses for transmitting clock, control, address and data signals. In FIG. 1, the terminal of the control component 10 to a semiconductor memory component 20 via an address bus CAB is shown on the left-hand side of the module board. The control component 10 has address terminals A0 . . . A15, to which a respective bus line for transmitting the address signals AS0 . . . AS15 is connected. The address signals AS0 . . . AS15 are supplied to address terminals CA0 . . . CA15 of the semiconductor memory component 20.

Each of the semiconductor memory components contains at least one memory chip. FIG. 2 shows a simplified illustration of a memory chip 21 including a memory cell array 210 with memory cells arranged along word lines and bit lines. Within the memory cell array, a memory cell SZ1 is connected between a word line WL1 and a bit line BL1. A further memory cell SZ2 is connected between a word line WL2 and a bit line BL2.

In the case of DRAM (Dynamic Random Access Memory) memory cells, a memory cell includes a selection transistor AT and a storage capacitor SC. For a read or write access operation to one of the memory cells, the associated selection transistor AT is turned on by an appropriate signal on the word line, therefore the associated storage capacitor SC is conductively connected to the connected bit line.

The memory cells SZ1 and SZ2 can be selected via a respective address AD1 or AD2. Each of the addresses AD1 and AD2 includes a plurality of address bits supplied to the address terminals CA0 . . . CA15 in the memory chip in the form of address signals AS0 . . . AS15. The supplied address signals or address bits are buffer-stored in an address register circuit 220. Based on the address bits of an address buffer-stored in the address register 220, it is possible to select one of the memory cells in the memory cell array 210.

Such semiconductor memory modules, such as DIMMs (Dual In-Line Memory Module), use semiconductor memory components from the generation Double Data Rate 2 (DDR2) or Double Data Rate 3 (DDR3). Semiconductor memory components from the generation DDR2 are generally operated at a supply voltage of 1.8 volts. The operating frequency in the case of such semiconductor memory components is in the range between 533 MHz and 800 MHz. Semiconductor memory components from the generation DDR3 are actuated using a supply voltage of 1.5 volts. Such semiconductor memory components are operated at operating frequencies of between 1066 MHz and 1600 MHz.

Semiconductor memory components from the generation DDR2 and DDR3 have respective address terminals which are arranged on the underside of a package of the semiconductor memory components. The association between the address terminals and the address signals is different for semiconductor memory components from different generations. Therefore, address terminals of DDR2 and DDR3 semiconductor memory components, which are situated on the underside of a package at the same position, are supplied with different address signals.

FIG. 3A shows a cut-out from address terminals which are arranged on the underside of a package of a semiconductor memory component from the generation DDR2. Address terminals CA6, CA11, CA15, which are situated on the underside of a semiconductor memory component from the generation DDR2 at a position AI, AII and AIII, are supplied with address signals AS6, AS11 and AS15. Address terminals CA4, CA8 and CA13, which are situated on the underside of a semiconductor memory component from the generation DDR2 at a position BI, BII and BIII, are supplied with address signals AS4, AS8 and AS13.

FIG. 3B shows the distribution of address terminals which are situated at the same positions AI, AII, AIII, BI, BII, and BIII on the underside of the package of a semiconductor memory component from the generation DDR3. Address terminals CA1, CA11 and CA14, which are situated at a position AI, AII and AIII, are supplied with the address signals AS1, AS11 and AS14. In addition, address terminals CA4, CA6 and CA8, which are situated at a position BI, BII and BIII on the underside of a package of a semiconductor component from the generation DDR3, are supplied with address signals AS4, AS6 and AS8.

Since address terminals which, in the case of semiconductor memory components from the generations DDR2 and DDR3, are situated at the same position on the underside of a package, are supplied with different address signals, it is generally not possible in a semiconductor memory module to replace the semiconductor memory components from one generation with the semiconductor memory components from another generation without altering the structure of the bus lines which are routed from the control component to the semiconductor memory components. The board layout therefore needs to be changed if a module board which was designed for semiconductor memory components from the generation DDR2 is intended to be fitted with semiconductor memory components from the generation DDR3 or if a module board which was designed for semiconductor memory components from the generation DDR3 is intended to be fitted with semiconductor memory components from the generation DDR2.

In addition, it will generally be necessary to alter the position of the address terminals of the control component on the basis of the generations of semiconductor memory components which are used in a semiconductor memory module. Consequently, the circuit design of the control component also needs to be changed. Replacing semiconductor memory components from one generation with semiconductor memory components from another generation on a semiconductor memory module therefore requires a high level of associated design complexity.

### SUMMARY

The invention relates to a control component for controlling at least one semiconductor memory component in a semiconductor memory module, the control component being connected to the at least one semiconductor memory component via various buses for transmitting control and address signals. The invention also relates to a semiconductor memory module comprising a control component. In addition, the invention relates to a method for operating a semiconductor memory module including a control component.

The control component includes an address generator circuit for generating address signals. The address generator circuit generates different address signals based on the input of a configuration signal. The control component is operable to actuate semiconductor memory components from different generations, e.g., from the generations DDR2 and DDR3.

The above and still further features and advantages of the described device will become apparent upon consideration of the following definitions, descriptions and descriptive figures of specific embodiments thereof, wherein like reference numerals in the various figures are utilized to designate like components. While these descriptions go into specific details of the device, it should be understood that variations may and do exist and would be apparent to those skilled in the art based on the descriptions herein.

### BRIEF DESCRIPTION OF THE DRAWINGS

The device is explained in more detail below with reference to exemplary embodiments, where:

FIG. 1 shows an embodiment of a semiconductor memory module with a control component connected to semiconductor memory components via an address bus;

FIG. 2 shows an embodiment of a memory chip with a memory cell array in a semiconductor memory component in a semiconductor memory module;

FIG. 3A shows an embodiment of address terminals for applying address signals in the case of a semiconductor memory component from a first generation;

FIG. 3B shows an embodiment of address terminals for applying address signals in the case of a semiconductor memory component from a second generation;

FIG. 4 shows an embodiment of a control component for controlling semiconductor memory components in a semiconductor memory module;

FIG. 5A shows an embodiment of address terminals of a semiconductor memory component from a first generation with associated address terminals of a control component disposed on a semiconductor memory module; and

FIG. 5B shows an embodiment of address terminals of a semiconductor memory component from a second generation with associated address terminals of a control component on a semiconductor memory module.

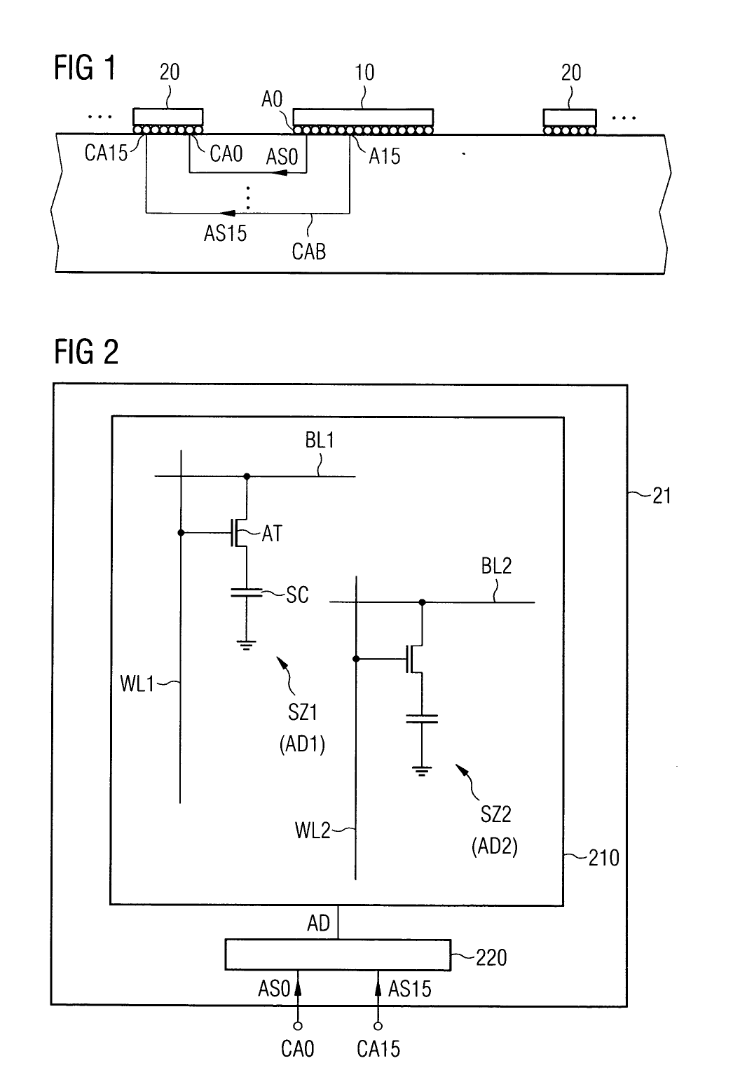

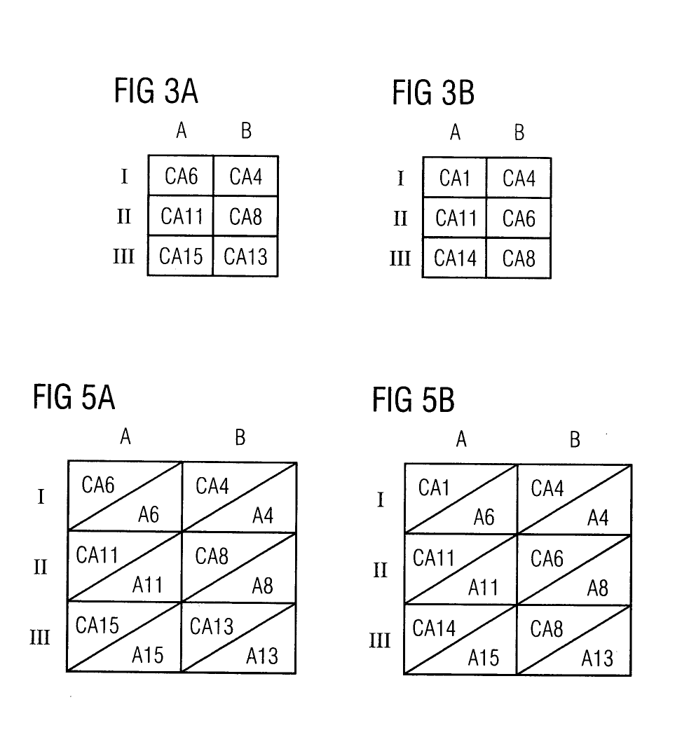

### DETAILED DESCRIPTION

According to an embodiment of a control component for controlling at least one semiconductor memory component in a semiconductor memory module described herein, the control component is operable to control semiconductor memory components from different generations. Furthermore, a semiconductor memory module comprising a control component for controlling at least one semiconductor memory component is specified wherein the control component is operable to control semiconductor memory components from different generations. Also a method for operating a semiconductor memory module is specified wherein a control component is used for controlling at least one semiconductor memory component in the semiconductor memory module, with the control component being operable to control semiconductor memory components from different generations.

According to an embodiment of a control component for controlling at least one semiconductor memory component in a semiconductor memory module, the control component comprises address terminals for providing an address comprising a plurality of address signals, the address being suitable for selecting one of a plurality of memory cells in the at least one semiconductor memory component for memory access. The control component also comprises an address generator circuit for generating the address signals. The address generator circuit is designed such that it selectively generates a first of the address signals from the address or a second of the address signals from the address on one of the address terminals.

The control component is operable to control semiconductor memory components from different generations. First, by generating different address signals on the same address terminals, it is possible for semiconductor memory components from the generation DDR2 and DDR3, e.g., to be actuated by the control component. Therefore, it is possible to replace semiconductor memory components from one generation with semiconductor memory components from the other generation on a module board without altering the design of the module board.

According to an embodiment of a semiconductor memory module, the semiconductor memory module comprises a control component for controlling at least one semiconductor memory component in a semiconductor memory module based on the embodiment of the control component described above. In addition, the semiconductor memory module comprises a memory circuit for storing at least one memory state and a module board on which the control component, the at least one semiconductor memory component and the memory circuit are disposed. The output of the memory circuit generates the configuration signal on the basis of the at least one memory state. The address generator circuit in the control component selectively generates the first of the address signals or the second of the address signals on the one of the address terminals based on the configuration signal.

According to an embodiment of a method for operating a semiconductor memory module based on the embodiment of the semiconductor memory module described above, the control component is operated in a first or second configuration based on the operating frequency or the supply voltage for the at least one semiconductor memory component. The first of the address signals is generated at one of the address terminals when the control component is being operated in the first configuration. The second of the address signals is generated at one of the address terminals when the control component is being operated in the second configuration.

In the following paragraphs, exemplary embodiments of the device and method are described in connection with the figures.

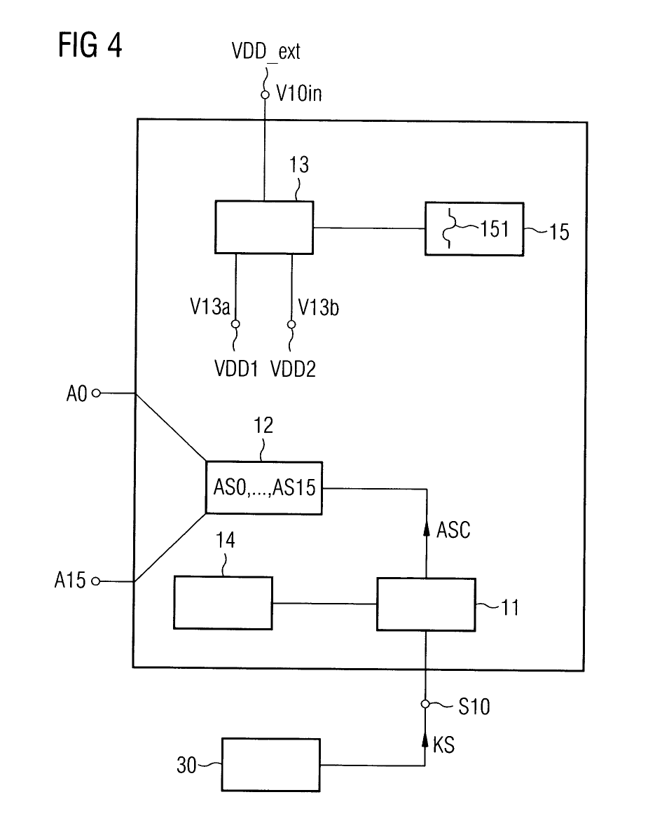

FIG. 4 shows an embodiment of a control component which is operable to both control semiconductor memory components from a first generation, e.g., the generation DDR2, and control semiconductor memory components from a second generation, e.g., the generation DDR3. The control component 10 comprises an address generator circuit 12 connected to address terminals A0 . . . A15. The address generator circuit generates address signals AS0 . . . AS15 (e.g., sixteen address bits). The address generator circuit is controlled via a control circuit 11 with a control signal ASC. On the basis of the control signal ASC, it is possible to generate the address signals AS0 . . . AS15 on various ones of the address terminals A0 . . . A15. In other words, the address generator circuit maps the address signals AS0 . . . AS15 (e.g., address bits) to the address terminals A0 . . . A15 in different ways as a function of the state of the control signal ASC.

In a first embodiment of the control component, the control circuit 11 is connected to a programming circuit 14. In a second embodiment of the control component, the control circuit 11 is connected to a control terminal SI 0 for supplying a configuration signal KS. The control terminal S10 is connected to a memory circuit 30 arranged on the module board. For example, the memory circuit 30 can be in the form of an electrically programmable memory circuit, e.g., in the form of an Electrically Programmable Read-Only Memory (EPROM) circuit.

In the following, the functionality of the control component 10 is further described. When a semiconductor memory module including the control component 10 is being activated, the programming circuit 14 or the memory circuit 30 is read. The programming state of the programming circuit 10 or the memory state of the memory circuit 30 indicates whether the semiconductor memory module comprises semiconductor memory components from a first generation, e.g., the generation DDR2, or semiconductor memory components from a second generation, e.g., the generation DDR3.

Based on the programming state of the programming circuit or the memory state of the memory circuit 30, the control circuit 11 generates the control signal ASC supplied to the address generator circuit 12. Based on the state of the control signal ASC, the address generator circuit 12 generates the address signals AS0 . . . AS15 at various ones of the address terminals A0 . . . A15, with the mapping of the address signal AS0 . . . AS15 to the address terminals A0 . . . A15 being different in the case where a DDR2 memory component will receive the address signals (e.g., address bits) than in the case where a DDR3 memory component will receive the address signals.

Therefore, the address generator circuit 12 allows the same module board MP with its internal bus structure for transmitting address signals to be used both when fitting the module board with semiconductor memory components from the first generation and when fitting it with semiconductor memory components from the second generation. The functionality of the address generator circuit 12 operable to generate different address signals at an address terminal based on the module board being fitted with semiconductor memory components from different generations, is further described below with reference to FIGS. 5A and 5B.

FIG. 5A shows the association between address terminals CA4, CA6, CA8, CA11, CA13 and CA15 of a semiconductor memory component from a first generation and address terminals A4, A6, A8, A11, A13 and A15 of a control component via bus lines on a module board. FIG. 5B shows the association between address terminals CA1, CA4, CA6, CA8, CA11 and CA14 of a semiconductor memory component from a second generation and the address terminals A4, A6, A8, A11, A13 and A15 of the control component via the same bus lines on the module board.

As FIG. 5A shows, for example, the address terminal A4 of the control component 10 is connected to the address terminal CA4 of the semiconductor memory component from the first generation via a bus line in the address bus CAB. In addition, the address terminals A6, A8, A11, A13 and A15 of the control component 10 are connected via appropriate bus lines in the address bus CAB to an address terminal CA6 of the semiconductor component from the first generation for applying an address signal AS6, to an address terminal CA8 for applying an address signal AS8, to an address terminal CA11 for applying an address signal AS11, to an address terminal CA13 for applying an address signal AS13 and to an address terminal CA15 for applying an address signal AS15.

Hence, when the module board is fitted with semiconductor memory components from the first generation, the address generator circuit is controlled such that the control component generates at the address terminal A4 an address signal AS4 which is supplied to the address terminal CA4 of the semiconductor memory component. Accordingly, the other address terminals A6, A8, A11, A13 and A15 of the control component have address signals AS6, AS8, AS11, AS13 and AS15 generated on them which are supplied to the address terminals CA6, CA8, CA1, CA13 and CA15.

As FIG. 5B shows, the position Al on the semiconductor memory component from the second generation comprises the address terminal CA1, to which the address signal AS1 needs to be supplied. Since the address terminal at the position AI on the underside of the package of the semiconductor memory component continues to be connected to the address terminal A6 of the control component, the address generator circuit is actuated such that the address signal AS1 is generated on the address terminal A6 of the control component. Accordingly, the address signal AS4, which is supplied to the address terminal CA4 of the semiconductor memory component, is generated on the address terminal A4 of the control component and the address signal AS6, which is supplied to the address terminal CA6 of the semiconductor memory, is generated on the address terminal A8. The address terminal A13 of the control component, which is connected to the address terminal CA8 of the semiconductor memory component for applying the address signal AS8, has the control signal AS8 generated on it, and the address terminal A15 of the semiconductor memory component, which is connected to the address terminal CA14 of the semiconductor memory component for applying the address signal AS14, has the address signal AS 14 generated on it. The address terminal A11 of the control component continues to have the address signal AS11 generated on it, which is supplied to the address terminal CA11 of the semiconductor memory component. It therefore becomes possible to leave the internal structure, particularly the arrangement of the address buses on the module board and also the address terminals of the control component, unchanged.

Thus, under control of the control circuit 11, the address generator circuit is capable of mapping individual address signals ASᵢ (e.g., individual address bits) to different address terminals Aⱼ so that a single controller and bus structure can accommodate a variety of memory components with differently configured address terminals. The memory circuit 30 or the programming circuit 14 are operable to store a plurality of memory states or programming states. It is thus possible to store association tables on the memory circuit or on the programming circuit, which provide the mapping of the address signals to controller address terminals for particular memory components. The association tables indicating which of the address signals AS0, . . . , AS15 needs to be generated by the address generator circuit 12 on which of the address terminals A0, . . . , A15. Therefore, different generations of semiconductor memory components can be placed on a semiconductor memory module without needing to change the design of the module board or the position of the address terminals of the control component.

In the event that the semiconductor memory components from different generations include individual address terminals situated at different positions, then the interconnect routing for these address lines on the module board needs to be changed. Since a plurality of the address terminals continue to be situated at the same physical positions on the underside of a package, however, and only the association between the address terminals and address signals is swapped, the interconnects' routing does not need to be changed for most of the address signals. Thereby, a significant improvement in the flexibility for a module design with the indicated form of the control component can be achieved.

Generally, semiconductor memory components from different generations operate at different supply voltages. Therefore, for example, memory chips from the generation DDR2 operate at a supply voltage of, e.g., 1.8 volts, whereas memory chips from the generation DDR3 operate at a supply voltage of, e.g., 1.5 volts. Depending on whether the control component is being operated on a DDR2 module or on a DDR3 module, the control component is supplied with different levels of an external supply voltage VDD_ext via the mother board in an application.

The control component 10 comprises a controllable switching unit 13 connected to a terminal V10 in for applying the external supply voltage VDD_ext. Depending on whether the semiconductor memory module comprises semiconductor memory components from the generation DDR2 or from the generation DDR3, the controllable switching unit is supplied with different levels of the external supply voltage. For example, the control component is supplied with a level of 1.5 volts if the module is fitted with semiconductor memory components from the generation DDR3, and an external supply voltage level of 1.8 volts is supplied if the module is fitted with semiconductor memory components from the generation DDR2. The different levels VDD1 or VDD2 of the supply voltage are provided on different internal terminals V13a and V13b of the controllable switching unit 13. The internal terminal V13a supplies the level VDD1, for example the level of 1.5 volts, to a DDR3 domain of the control component. The internal terminal V13b supplies the level VDD2, for example the level of 1.8 volts, to a DDR2 domain of the control component.

The controllable switching unit 13 is connected to a memory unit 15 which comprises a plurality of fuse components 151, for example. The memory unit 15 has previously been programmed during production of the semiconductor memory module. The memory state or the state of the fuse components indicates whether the control component is being used on a DDR2 module or a DDR3 module. The memory unit 15 thus provides the controllable switching unit 13 with the information regarding whether the level of the supply voltage needs to be provided on the internal terminal V13a in the case of a DDR3 module or on the internal terminal V13b in the case of a DDR2 module.

While the device has been described in detail with reference to specific embodiments thereof, it will be apparent to one of ordinary skill in the art that various changes and modifications can be made therein without departing from the spirit and scope thereof. Accordingly, it is intended that the described device covers the modifications and variations of this described device provided they come within the scope of the appended claims and their equivalents.

What is claimed is:

1. A control component for controlling at least one semiconductor memory component in a semiconductor memory module, comprising:
a plurality of address terminals for supplying a respective plurality of address signals of an address for selecting one of a plurality of memory cells in the at least one semiconductor memory component for memory access; and
an address generator circuit for generating the address signals, wherein the address generator circuit is operable to selectively map a first of the address signals or a second of the address signals to one of the address terminals.

2. The control component as claimed in claim 1, wherein the address generator circuit maps the first or second of the address signals to said one of the address terminals based on an operating frequency of the at least one semiconductor memory component.

3. The control component as claimed in claim 1, wherein the address generator circuit maps the first or second of the address signals to said one of the address terminals based on a level of an operating supply voltage of the at least one semiconductor memory component.

4. The control component as claimed in claim 1, further comprising an external control terminal for applying a configuration signal, wherein the address generator circuit maps the first or second of the address signals to said one of the address terminals based on the configuration signal.

5. The control component as claimed in claim 4, further comprising:
a supply terminal for applying a first or second level of an external supply voltage; and
a controllable switching unit with a first output terminal for providing a first level of an internal supply voltage and a second output terminal for providing a second level of the internal supply voltage, wherein the controllable switching unit is connected to the supply terminal.

6. The control component as claimed in claim 5, wherein the controllable switching unit selectively generates one of the first and second levels of the internal supply voltage at one of the first and second output terminals of the controllable switching unit based on an operating frequency of the at least one semiconductor memory.

7. The control component as claimed in claim 5, further comprising:
a programming circuit for programming a programming state;
wherein the address generator circuit maps the first or second of the address signals to said one of the address terminals based on the programming state.

8. The control component as claimed in claim 7, further comprising a memory unit for storing a memory state, wherein the controllable switching unit selectively generates one of the first and second levels of the internal supply voltage at one of the first and second output terminals of the controllable switching unit based on the memory state of the memory unit.

9. The control component as claimed in claim 8, wherein the memory unit comprises fuse components.

10. The control component as claimed in claim 1, wherein the control component is a hub chip for the semiconductor memory module.

11. The control component as claimed in claim 1, wherein the address signals are address bits of the address.

12. A semiconductor memory module, comprising:
a control component for controlling at least one semiconductor memory component in a semiconductor memory module as claimed in claim 1;
a memory circuit for storing at least one memory state and for generating a configuration signal based on the at least one memory state; and
a module board on which the control component, the at least one semiconductor memory component, and the memory circuit are arranged;
wherein the address generator circuit of the control component maps the first or second of the address signals to said one of the address terminals based on the configuration signal.

13. The semiconductor memory module as claimed in claim 12, wherein the at least one memory state includes an association between respective ones of the address signals and respective ones of the address terminals of the control component.

14. The semiconductor memory module as claimed in claim 12, wherein the memory circuit is an electrically programmable memory circuit.

15. A method for operating a memory module comprising a control component which supplies an address for accessing a memory component, wherein address signals of the address are respectively supplied on address terminals of the control component, and the control component is capable of selectively mapping individual address signals of the address to certain of the address terminals, the method comprising:
operating the control component in a first or second configuration, wherein the first and second configurations are a function of an operating frequency of the memory component or an operating supply voltage of the memory component;
generating a first mapping of the address signals to the address terminals in response to the control component being operated in the first configuration; and
generating a second mapping of the address signals to the address terminals in response to the control component being operated in the second configuration.

16. The method as claimed in claim 15, wherein the memory module further comprises a memory circuit storing a memory state, the method further comprising:
reading the memory state of the memory circuit; and
operating the control component in the first or the second configuration based on the memory state of the memory circuit.

17. The method as claimed in claim 15, wherein the control component further comprises a memory unit for storing a memory state and a controllable switching unit with a first output terminal for providing a first level of an internal supply voltage and a second output terminal for providing a second level of the internal supply voltage, the method further comprising:
reading the memory state from the memory unit in the control component;
generating the first level of the internal supply voltage at the first output terminal of the controllable switching unit in response to a first state of the memory unit of the control component; and
generating the second level of the internal supply voltage at the second output terminal of the controllable switching unit in response to a second state of the memory unit of the control component, wherein the first and second levels of the internal supply voltage are used to select the first and second mappings, respectively.
